(19) United States
(12) Patent Application Publication
(10) Pub. No.: US 2026/0165137 A1
(43) Pub. Date: Jun. 11, 2026

(54) SUBSTRATE HAVING INTEGRATED STRESS RELIEF STRUCTURE

(71) Applicant: Micron Technology, Inc., Boise, ID (US)

(72) Inventors: Kimball Davis LOWRY, Boise, ID (US); Bradley Russell BITZ, Taichung City (TW); Joao Elmiro CHAVES, Middleton, ID (US); David R. CHRISTIANSON, Meridian, ID (US)

(21) Appl. No.: 19/179,126

(22) Filed: Apr. 15, 2025

Related U.S. Application Data
(60) Provisional application No. 63/659,167, filed on Jun. 12, 2024.

(51) Int. Cl. H10W 42/00; H01R 12/72

(52) U.S. Cl. CPC H10W 42/121; H01R 12/721

(57) ABSTRACT

Implementations described herein relate to various structures, integrated assemblies, and memory devices. In some implementations, an integrated assembly includes a substrate having a conductive layer and an integrated stress relief structure having a portion that passes through the conductive layer.

### CROSS-REFERENCE TO RELATED APPLICATION

This Patent Application claims priority to U.S. Provisional Patent Application No. 63/659,167, filed on Jun. 12, 2024, entitled “SUBSTRATE HAVING INTEGRATED STRESS RELIEF STRUCTURE,” and assigned to the assignee hereof. The disclosure of the prior Application is considered part of and is incorporated by reference into this Patent Application.

### TECHNICAL FIELD

The present disclosure generally relates to integrated semiconductor assemblies that include multi-layer substrates, and more specifically to a multi-layer substrate having integrated stress relief structures.

### BACKGROUND

An electronic system assembly, such as a memory module, may include multiple semiconductor die packages electrically coupled to a multi-layer substrate, such as a printed circuit board (PCB). The PCB may include a layer stack having dielectric layers interspersed with conductive layers. The PCB may include electrical interconnects and conductive paths through the layer stack that are used for interconnecting system components, including the multiple semiconductor die packages and other components that may be used to enable functionality of the memory module in a host computing system.

For compatibility and/or functionality purposes, industry standards such as Joint Electron Device Engineering Council (JEDEC) standards may impose one or more physical and/or dimensional thresholds on the PCB. An example of such a physical and/or dimensional threshold is a straightness threshold.

### BRIEF DESCRIPTION OF THE DRAWINGS

FIG. 1 is an example implementation of an integrated assembly including a substrate having an integrated stress relief structure described herein.

FIG. 2 is an example implementation of an integrated assembly including a substrate having an integrated stress relief structure described herein.

FIGS. 3A-3C are diagrammatic views showing example implementations of a substrate having an integrated stress relief structure described herein.

FIG. 4 is a diagrammatic view of example implementations of a recessed region included in a substrate described herein.

FIG. 5 is a flowchart of an example method of forming an integrated assembly or memory device having a substrate with an integrated stress relief structure.

FIG. 6 is a flowchart of an example method of forming an integrated assembly or memory device having a substrate with an integrated stress relief structure.

FIGS. 7A-7C are diagrammatic views showing formation of a substrate including an integrated stress relief structure at example process stages of an example process of forming the substrate.

### DETAILED DESCRIPTION

Printed circuit boards (PCBs) and other substrates are fundamental components in electronic devices that provide mechanical support and electrical connections for various electronic components. One of the challenges in the design and manufacture of PCBs is managing mechanical stress, which can lead to warpage and bending of the PCB such that the PCB fails to satisfy a straightness threshold. Warpage is particularly problematic as it can affect solder joint reliability, lead to misalignments during component placements, and cause fit and connectivity issues in the final assembly, which compromises device performance and reliability.

Additionally, managing heat dissipation is critical in electronic devices to maintain optimal performance and prevent overheating that can damage components. Traditional methods of heat management often involve complex designs and may not address localized hotspots effectively. Furthermore, the integration of labels and protective features for sensitive components typically necessitates additional components or layers, which can increase manufacturing complexity and costs.

In some cases, improving structural support involves use of additional materials or layers, which can inadvertently increase the thermal and mechanical stress on the PCB or substrate. There is also a need to protect sensitive components from physical stresses, especially as designs trend towards higher component densities and closer placement to board edges. The challenges associated with these needs include balancing mechanical behavior, enhancing lamination, increasing heat extraction

efficiency, and protecting components without significantly increasing production steps or costs. Moreover, improved aesthetics for labels and re-labeling flexibility are sought after for consumer appeal and practicality in rework situations.

Therefore, the technical problems addressed include how to reduce warpage by balancing mechanical stresses, create a robust interface for surface mount components, improve heat dissipation, support and protect sensitive components, provide label support, and ultimately enhance the yield and reliability of electronic devices while potentially reducing the overall number of manufacturing steps and costs.

Some implementations described herein involve the technical enhancement of mechanical and thermal properties of substrates, such as printed circuit boards (PCBs), including an integrated stress relief structure. Specifically, a method includes receiving a multi-layer substrate including a conductive layer and an insulative layer, and forming a recessed region in the multi-layer substrate that exposes edges of both the conductive and integrated layers. An integrated stress relief structure is then formed, with portions extending into the recessed region to interface directly with the exposed edges of the conductive and insulative layers.

The integrated stress relief structure may be formed using a composite material that combines an epoxy mold compound with thermally-conductive particulates. This innovative mix elevates the thermal conductivity beyond what the epoxy mold compound could achieve on its own. The formation of the recessed region, expressed as elongated channels or vias, can be partial or entirely through the multi-layer substrate, thereby improving the structural integrity and thermal management capabilities of the substrate assembly.

In this way, the integrated stress relief structure mitigates against thermal loads, which is beneficial for maintaining functionality of semiconductor components. Furthermore, by employing portions that integrate within or traverse through the substrate, the integrated stress relief structure balances stresses, thereby reducing potential warpage and bending of the substrate. Interplay between the mold compound and substrate materials not only advances lamination techniques, but also facilitates augmented heat dissipation through increased surface contact and enhanced conductivity due to the thermally conductive properties of the integrated stress relief structure. Further, the implementation the integrated stress relief structure may provide protection for sensitive components, support for surface mount components during molding processes, and (where applicable) label support that could supplant dummy components, which in turn could conserve real estate of the multi-layer substrate.

These implementations may contribute to improved yield and reliability of electronic devices by delivering structural rigidity, minimizing mechanical stresses, reducing warpage, and enhancing thermal distribution, effectively conserving resources such as materials and manufacturing time. Additionally, these technical improvements can lead to improvements in system compatibility as well as a technical means for label application without relying on additional components, thereby reducing overall costs and manufacturing complexity. Furthermore, the quality and/or reliability of the semiconductor device is improved. By improving the quality and/or the reliability of the semiconductor device, an amount of resources used to support a market consuming the semiconductor device (e.g., raw materials, semiconductor manufacturing tools, labor, and/or computing resources) is reduced.

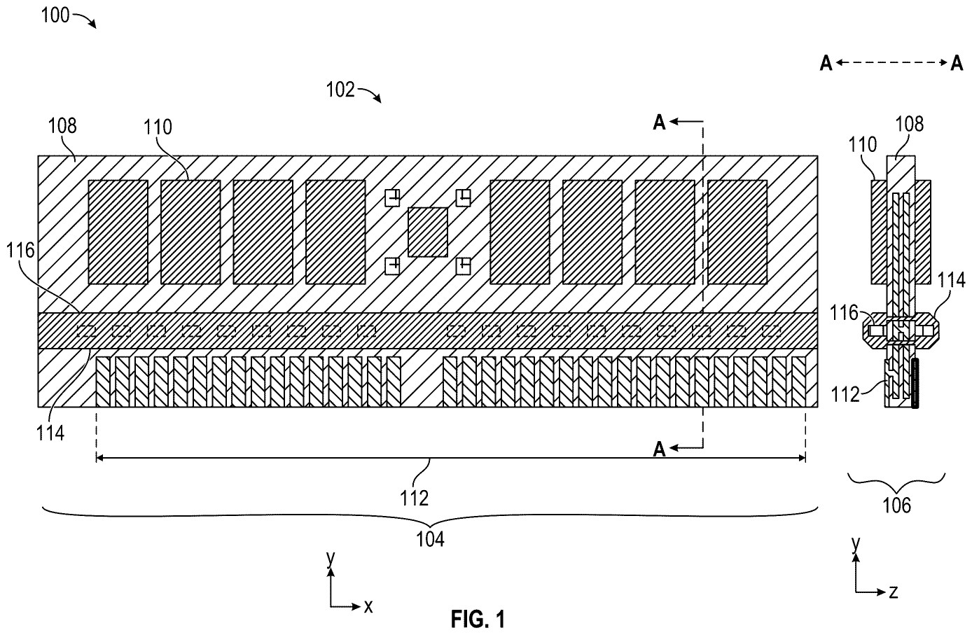

FIG. 1 is an example implementation 100 of an integrated assembly including a substrate having an integrated stress relief structure described herein. In some implementations, and as shown in FIG. 1, the integrated assembly may be a memory module 102. In some implementations, the memory module 102 is included in a computing device such as a server, a computer, a mobile phone, a wired or wireless communication device, a network device, a device in a data center, a device in a cloud computing environment, a vehicle (e.g., an automobile or an airplane), and/or an Internet of Things (IoT) device.

FIG. 1 includes a front view 104 and a side section view 106 (e.g., a section view along section line A-A) of the memory module 102. As shown in the front view 104 of FIG. 1, the memory module 102 includes a substrate 108 (e.g., an interposer). The substrate 108 may be a multi-layer substrate that includes a combination of dielectric layers and conductive layers that are interspersed with one another in a vertically-arranged stack. For example, and in some implementations, the substrate 108 corresponds to a printed circuit board (PCB) type of substrate that includes dielectric layers having fiberglass-reinforced epoxy resin material interspersed with conductive layers having a metal material such as a copper material or an aluminum material, among other examples. As another example, and in some implementations, the substrate 108 corresponds to an interposer type of substrate that includes dielectric layers having a ceramic material interspersed with conductive layers having a metal material such as a silver material or a gold material, among other examples. However, other types of substrates and/or combinations of materials for the dielectric layers and/or the conductive layers are within the scope of the present disclosure.

As further shown in the front view 104 of FIG. 1, the memory module 102 is populated with semiconductor die packages 110. Each of the semiconductor die packages 110 may be a ball grid array (BGA) type of semiconductor die package or a thin small outline package (TSOP) type of semiconductor die package, among other examples. In some implementations, each of the semiconductor die packages 110 includes a casing (e.g., an epoxy mold compound) that encapsulates at least one integrated circuit die. The integrated circuit die may include a memory device such as a DRAM memory device, among other examples. Additionally, or alternatively, the integrated circuit die may include a power management device, an inductor device, or a voltage regulator device. The semiconductor die packages 110 may be mounted and/or connected to pads of the memory module 102.

The memory module 102 further includes a linear array of edge connector pads 112. The linear array of edge connector pads 112, which may include a conductive material such as a copper material or an aluminum material, may communicatively couple the memory module 102 to a computing device that hosts the memory module 102.

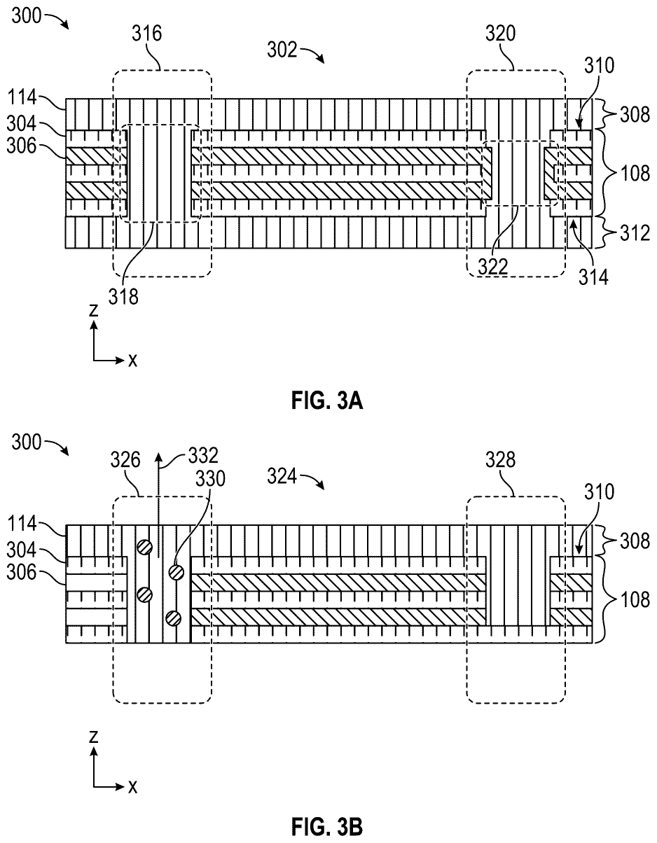

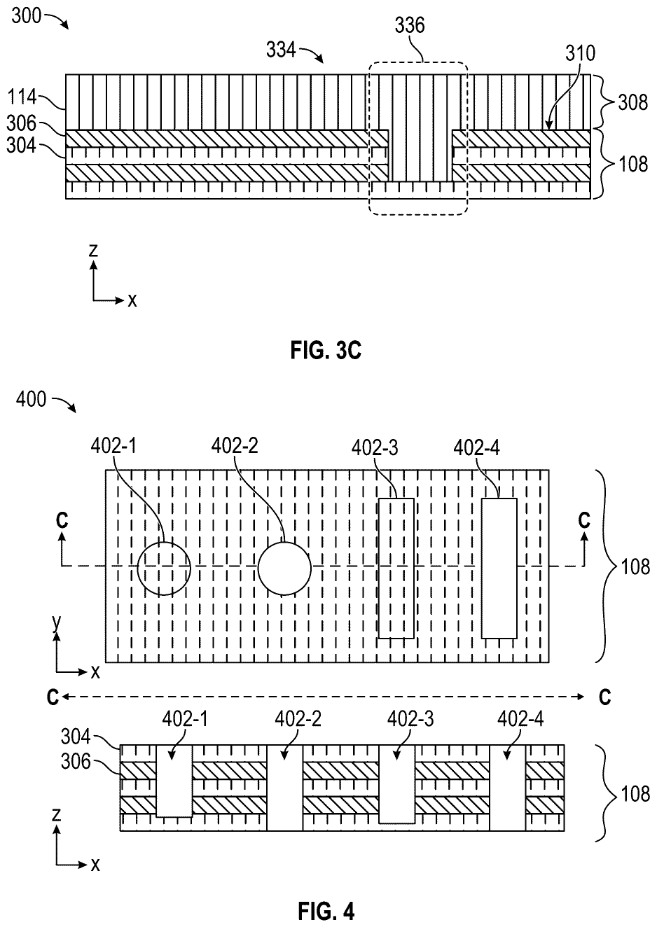

As further shown in the front view 104 of FIG. 1, the memory module 102 includes a stress relief structure 114. As described in greater detail in connection with FIGS. 3A-7, the stress relief structure 114 may include an epoxy mold compound and be integrated with the substrate 108. For example, in some implementations and shown in the side section view 106, the stress relief structure 114 passes through the substrate 108 (e.g., passes through dielectric layers and/or conductive layers of the substrate 108).

The stress relief structure 114 may include one or more beam-like structures that are configured to absorb and/or balance one or more mechanical stresses (a bending stress, a compressive stress, and/or a tensile stress in megapascals (mPA), among other examples) to maintain a straightness and/or a flatness of the memory module 102. For example, and as shown in FIG. 1, the stress relief structure 114 is a beam-like structure that is disposed proximate to the linear array of edge connector pads 112 and along a path that is approximately parallel to the linear array of edge connector pads 112. By absorbing and/or balancing one or more of a bending stress, a compressive stress, and/or a tensile stress that may be induced to the substrate 108 during assembly of the memory module 102, the stress relief structure 114 may maintain a straightness and/or a flatness of the memory module 102 to satisfy a threshold. In doing so, a reliability of solder joints used to mount the semiconductor die packages 110 may be increased. Additionally, or alternatively, a compatibility of the linear array of edge connector pads 112 with an electrical connector of an end-use system (e.g., a socket of a computing system) may be increased.

As further shown in FIG. 1, and in some implementations, the stress relief structure 114 encapsulates at least one integrated circuit component 116 joined with (e.g., surface mounted to) the substrate 108 to protect the integrated circuit component 116 from damage, contamination, and/or moisture. In some implementations, the integrated circuit component 116 includes passive integrated circuitry (capacitor integrated circuitry, inductor integrated circuitry, and/or resistor integrated circuitry, among other examples).

In some implementations, the stress relief structure 114 includes an epoxy mold compound that includes an epoxy resin, fillers, and/or curing agents. Alternatively, the stress relief structure 114 may include a silicone mold compound, a liquid crystal polymer mold compound, a polyphenylene sulfide mold compound, a phenolic mold compound, a ceramic mold compound, or another suitable mold compound, among other examples.

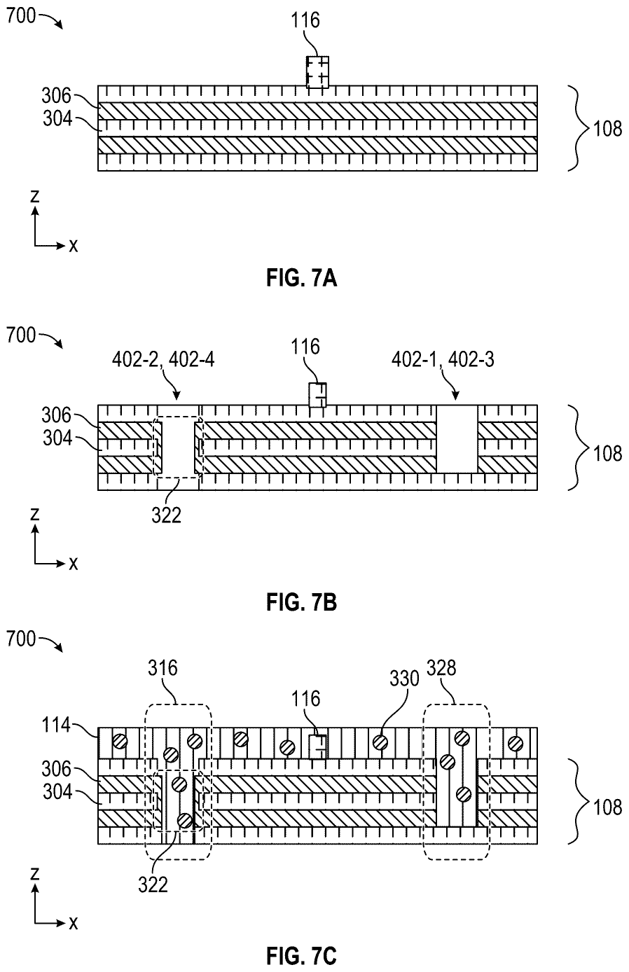

In some implementations, and as described in greater detail in connection with FIG. 3B, FIG. 7C, and elsewhere herein, the stress relief structure 114 may include one or more thermal properties that increase heat dissipation from the memory module 102. For example, an epoxy mold compound included in the stress relief structure 114 may have a thermal conductivity (e.g., thermal conductivity in watts per meter Kelvin W/mK)) that is greater than a thermal conductivity of the substrate 108. Additionally, or alternatively, the stress relief structure 114 may include one or more thermally-conductive particulates that are dispersed (e.g., mixed) within the epoxy mold compound and that have a thermal conductivity that is greater than the thermal conductivity of the epoxy mold compound. By increasing the heat dissipation from the memory module 102, the stress relief structure 114 may help integrated circuity included in the semiconductor die packages 110 (e.g., DRAM integrated circuitry) satisfy a junction temperature threshold. In doing so, a reliability of the integrated circuitry may be increased.

As indicated above, FIG. 1 is provided as an example. Other examples may differ from what is described with regard to FIG. 1.

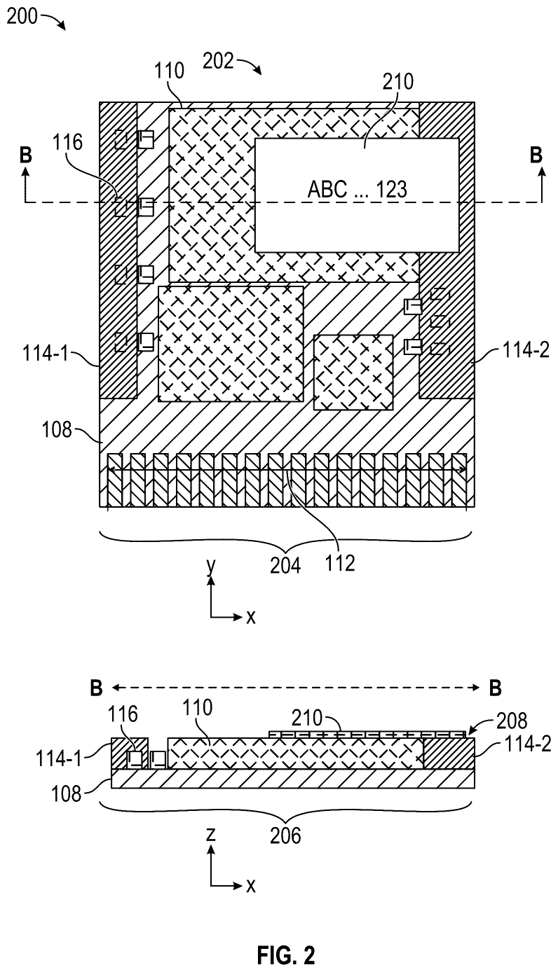

FIG. 2 is an example implementation 200 of an integrated assembly including a substrate having an integrated stress relief structure described herein. In some implementations, and as shown in FIG. 2, the integrated assembly may be a solid state drive (SSD) module 202. In some implementations, the SSD module 202 is included in a computing device such as a server, a computer, a mobile phone, a wired or wireless communication device, a network device, a device in a data center, a device in a cloud computing environment, a vehicle (e.g., an automobile or an airplane), and/or an Internet of Things (IoT) device.

FIG. 2 includes a front view 204 and a side section view 206 (e.g., a section view along section line B-B) of the SSD module 202. As shown in the front view 204 and the side section view 206 of FIG. 2, the SSD module 202 includes the substrate 108 and is populated with the with the semiconductor die packages 110. Each of the semiconductor die packages 110 of implementation 200 includes a casing (e.g., an epoxy mold compound) that encapsulates at least one integrated circuit die. The integrated circuit die may include a memory device such as a NAND memory device, among other examples.

As further shown in FIG. 2, the SSD module 202 includes the linear array of edge connector pads 112, the stress relief structure 114-1, and the stress relief structure 114-2. Additionally, or alternatively and as shown in FIG. 2, the stress relief structure 114-1 and/or the stress relief structure 114-2 may encapsulate one or more the one or more integrated circuit components 116.

As further shown in FIG. 2, the stress relief structure 114-1 may provide additional surface area in the way of an approximately planar surface region 208 for affixing a label 210 to the SSD module 202. By providing the additional surface area, the stress relief-structure 114-1 alleviates the need for dummy components being joined with the substrate 108 to provide support for the label 210. In doing so, the stress relief structure 114-1 may conserve real estate of the substrate 108.

As indicated above, FIG. 2 is provided as an example. Other examples may differ from what is described with regard to FIG. 1.

FIGS. 3A-3C are diagrammatic views showing example implementations 300 of a substrate (e.g., the substrate 108) having an integrated stress relief structure (e.g., the stress relief structure 114) described herein. As shown in FIGS. 3A-3C, the substrate 108 and the stress relief structure 114 may be included in a memory module (e.g., the memory module 102 of FIG. 1), an SSD module (e.g., the SSD module 202 of FIG. 2), or another integrated assembly, among other examples.

As shown in example 302 of FIG. 3A, the substrate 108 includes at least one dielectric layer 304 that is interspersed (e.g., arranged vertically in an alternating configuration) with at least one conductive layer 306. The dielectric layer 304 may include an insulative material such as fiberglass-reinforced epoxy laminate, polyimide, polytetrafluoroethylene, aluminum oxide, or another suitable insulative material among other examples. The conductive layer 306 may include conductive material such as aluminum, copper, gold, silver, or nickel, or another suitable conductive material, among other examples.

As shown in FIG. 3A, the stress relief structure 114 is a dual-sided stress relief structure that includes a portion 308 (e.g., a first, horizontal portion) over and/or on a side 310 (e.g., a first side or a top surface) of the substrate 108 and a portion 312 (e.g., a second, horizontal portion) over and/or on a side 314 (e.g., a second, opposite side or a bottom surface) of the substrate 108. Additionally, or alternatively and as shown in FIG. 3A, the portion 308 and/or the portion 312 may each be directly on (e.g., conjoined with) a dielectric layer (e.g., the dielectric layer 304).

As further shown in FIG. 3A, the stress relief structure 114 may include a portion 316 that passes through the substrate 108 (e.g., a vertical portion that passes through the conductive layer 306 and/or the dielectric layer 304) and that joins with the portions 308 and 312. In some implementations, the portion 316 may fill an un-plated via region 318 (e.g., an un-plated vertical interconnect access through-hole in the substrate 108) and join with an edge of the conductive layer 306 and/or the dielectric layer 304.

As further shown in FIG. 3A, the stress relief structure 114 may also include a portion 320 that passes through the substrate 108 (e.g., a vertical portion that passes through the dielectric layer 304 and/or the conductive layer 306) and that joins with the portions 308 and 312. However, and in contrast to the portion 316, the portion 320 may fill a plated via region 322 (e.g., a plated vertical interconnect access through-hole in the substrate 108) and join with plating that forms an interface across one or more dielectric layers 304 and/or one or more of the conductive layers 306.

As shown in example 324 of FIG. 3B, the stress relief structure 114 is a single-sided stress relief structure that includes the portion 308 over and/or on the side 310 of the substrate 108. Additionally, or alternatively and as shown in FIG. 3B, the portion 308 may be directly on (e.g., conjoined with) a dielectric layer (e.g., the dielectric layer 304). Further, and as shown in FIG. 3B, the stress relief structure 114 includes a portion 326 that passes through the substrate 108 and a portion 328 that penetrates partially into the substrate 108.

In some implementations, a substrate (e.g., the substrate 108) having an integrated stress relief structure (e.g., the stress relief structure 114) includes one or more features that improve a thermal performance. For example, and as shown in FIG. 3B, the portion 326 of the stress relief structure 114 may include thermally-conductive particulates 330 that are interspersed and/or mixed with a matrix of the stress relief structure 114 (e.g., interspersed and/or mixed with an epoxy mold compound to form a composite material). In some implementations, the thermally-conductive particulates 330 have a thermal conductivity that is greater than a thermal conductivity of the matrix. The thermally-conductive particulates may include aluminum oxide particulates, graphite particulates, aluminum particulates, silicon carbide particulates, boron nitride particulates, nanotube particulates, or other suitable thermally-conductive particulates, among other examples.

Additionally, or alternatively the matrix may have a thermal conductivity that is greater than a thermal conductivity of the substrate 108. Such a matrix, alone or in combination with the thermally-conductive particulates 330, may increase a rate at which heat 332 is transferred away from the substrate 108 and/or the stress relief structure 114.

As shown in example 334 of FIG. 3C, the stress relief structure 114 is a single-sided stress relief structure that includes the portion 308 over and/or on the side 310 of the substrate 108. However, and in contrast to FIGS. 3A and 3B (e.g., examples 302 and 324), the stress relief structure 114 is directly on (e.g., conjoined with) a conductive layer (e.g., the conductive layer 306) as opposed to a dielectric layer (e.g., the dielectric layer 304).

As further shown in FIG. 3C, the conductive layer 306 is an uppermost layer of the substrate 108 (as opposed to an intermediate layer as shown example 302 of FIG. 3A and example 324 of FIG. 3B). The stress relief structure 114 that is directly on the conductive layer 306 may reduce a thickness of the substrate 108 and/or a quantity of dielectric layers 304 included in the substrate 108.

In some implementations, reducing the thickness of the substrate 108 and/or the quantity of the dielectric layers 304 increases a thermal conductivity of the substrate 108 (e.g., reduces a thermal resistance). Additionally, or alternatively, reducing the thickness of the substrate 108 and/or the quantity of the dielectric layers 304 may enable the substrate 108 including the stress relief structure 114 to satisfy a size and/or a form factor threshold.

As indicated above, FIGS. 3A-3C are provided as one or more examples. Other examples may differ from what is described with regard to FIGS. 3A-3C.

FIG. 4 is a diagram of example implementations 400 of a recessed region (e.g., a recessed region 402) included in a substrate (e.g., the substrate 108) described herein. The recessed region 402 may accommodate one or more portions of a stress relief structure (e.g., the stress relief structure 114) described herein.

As shown in FIG. 4, the recessed region 402-1 may correspond to a via that penetrates partially into the substrate 108. Additionally, or alternatively, the recessed region 402-2 may correspond to a via that penetrates through the substrate 108. Although shown to have round shapes in FIG. 2, the recessed region 402-1 and/or the recessed region 402-1 may have a square shape, an elliptical shape, or a triangular shape, among other examples. The recessed region 402-1 may be selected for an implementation of a single-sided stress relief structure (e.g., a single sided implementation of the stress relief structure 114). The recessed region 402-2 may be selected for a dual-sided stress relief structure (e.g., a dual sided implementation of the stress relief structure 114).

As further shown in FIG. 4, the recessed region 402-3 may correspond to an elongated channel that penetrates partially into the substrate. Additionally, or alternatively, the recessed region 402-4 may correspond to an elongated channel that penetrates through the substrate 108. The recessed region 402-3 may be selected for an implementation of a single-sided stress relief structure (e.g., a single sided implementation of the stress relief structure 114) that has a beam-like configuration. The recessed region 402-2 may be selected for an implementation of a dual-sided stress relief structure (e.g., a dual-sided implementation of the stress relief structure 114) that has beam-like configurations.

As indicated above, FIG. 4 is provided as one or more examples. Other examples may differ from what is described with regard to FIG. 4.

As described in connection with FIGS. 1-4, and in some implementations, an integrated assembly may include a substrate (e.g., the substrate 108) and a stress relief structure (e.g., the stress relief structure 114) The substrate includes a conductive layer (e.g., the conductive layer 306) and the stress relief structure includes a portion (e.g., portion 316, the portion 320, the portion 326, the portion 328, and/or the portion 336) that passes through the conductive layer.

Additionally, or alternatively and in some implementations, a semiconductor device assembly (e.g., the memory module 102 and/or the SSD module 202) may include a multi-layer printed circuit board (e.g., the substrate 108). The multi-layer printed circuit board includes a first side (e.g., the side 310) and a second, opposite side (e.g., the side 314). The semiconductor device assembly includes an integrated stress relief structure (e.g., the stress relief structure 114) that includes a first portion (e.g., the portion 308) over the first side; and a second portion (e.g., the portion 312) over the second, opposite side.

Additionally, or alternatively and in some implementations, a semiconductor device assembly (e.g., the memory module 102 and/or or the SSD module 202) may include a multi-layer substrate (e.g., the substrate 108). The multi-layer substrate includes a recessed region (e.g., the recessed region 402-1, the recessed region 402-2, the recessed region 402-3, and/or the recessed region 402-4) that penetrates at least partially into the multi-layer substrate and exposes an edge of a conductive layer (e.g., the conductive layer 306) of the multi-layer substrate and an edge of a dielectric layer (e.g., the dielectric layer 304) of the multi-layer substrate. The semiconductor device assembly includes a stress relief structure (e.g., the stress relief structure 114). The stress relief structure includes a portion (e.g., the portion 316, the portion 320, the portion 326, the portion 328, and/or the portion 336) in the recessed region that is over the edge of the conductive layer and the edge of the dielectric layer.

In these ways, the implementations contribute to improved yield and reliability of electronic devices by delivering structural rigidity, minimizing mechanical stresses, reducing warpage, and enhancing thermal distribution, effectively conserving resources such as materials and manufacturing time. Additionally, these implementations may improve system compatibility and provide a means for label application without relying on additional components, thereby reducing overall costs and manufacturing complexity. Furthermore, the quality and/or reliability of the semiconductor device is improved. By improving the quality and/or the reliability of the semiconductor device, an amount of resources used to support a market consuming the semiconductor device (e.g., raw materials, semiconductor manufacturing tools, labor, and/or computing resources) is reduced.

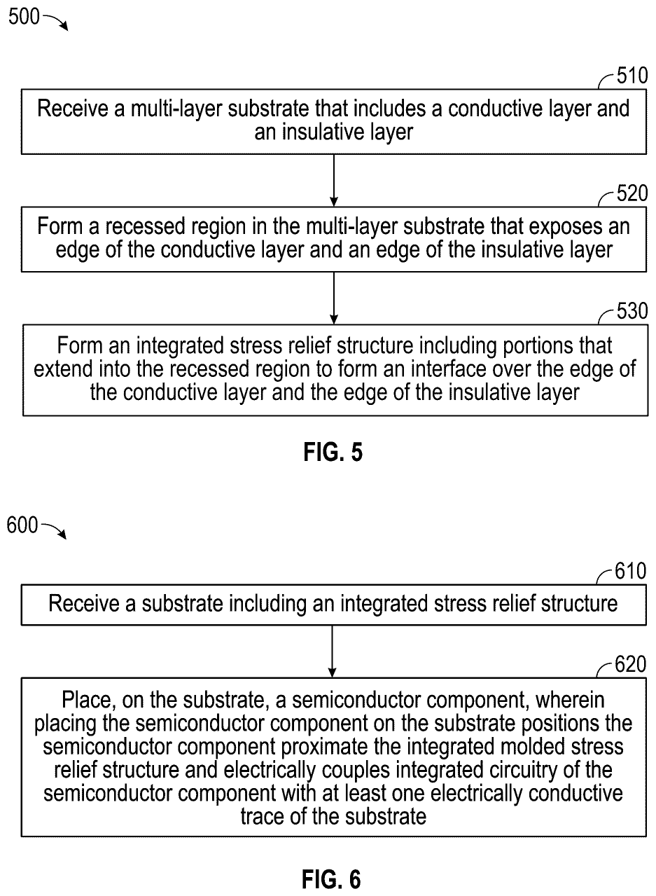

FIG. 5 is a flowchart of an example method 500 of forming an integrated assembly or memory device (e.g., the memory module 102 or the SSD module 202) having a substrate (e.g., the substrate 108) with an integrated stress relief structure (e.g., the stress relief structure 114). In some implementations, and as described in greater detail in connection with FIGS. 7A-7C, one or more process blocks of FIG. 5 may be performed by various semiconductor manufacturing equipment.

As shown in FIG. 5, the method 500 may include receiving a multi-layer substrate (e.g., the substrate 108) that includes a conductive layer (e.g., the conductive layer 306) and an insulative layer (e.g., the dielectric layer 304) (block 510). As further shown in FIG. 5, the method 500 may include forming a recessed region (e.g., the recessed region 402) in the multi-layer substrate that exposes an edge of the conductive layer and an edge of the insulative layer (block 520). As further shown in FIG. 5, the method 500 may include forming an integrated stress relief structure (e.g., the stress relief structure 114) including portions (e.g., the portion 316, the portion 320, the portion 326, the portion 328, and/or the portion 336) that extend into the recessed region to form an interface over the edge of the conductive layer and the edge of the insulative layer (block 530).

The method 500 may include additional aspects, such as any single aspect or any combination of aspects described below and/or in connection with one or more other methods described elsewhere herein.

In a first aspect, forming the integrated stress relief structure includes encapsulating at least one passive integrated circuit component (e.g., the integrated circuit component 116) that is joined with the multi-layer substrate.

In a second aspect, alone or in combination with the first aspect, forming the recessed region includes forming the recessed region using an etching operation, forming the recessed region using a routing operation, or forming the recessed region using a laser ablation operation.

In a third aspect, alone or in combination with one or more of the first and second aspects, the method 500 includes plating least a portion (e.g., the plated via region 322) of the recessed region prior to forming the integrated stress relief structure over the edge of the conductive layer and the edge of the insulative layer.

In a fourth aspect, alone or in combination with one or more of the first through third aspects, forming the integrated stress relief structure includes forming the integrated stress relief structure using a composite material that includes an epoxy mold compound mixed with thermally-conductive particulates (e.g., the thermally-conductive particulates 330). In some implementations, a thermal conductivity of the thermally-conductive particulates is greater than a thermal conductivity of the epoxy mold compound.

In a fifth aspect, alone or in combination with one or more of the first through fourth aspects, the method 500 includes placing a label (e.g., the label 210) on at least a portion of the integrated stress relief structure.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the integrated stress relief structure 114, an integrated assembly that includes the integrated stress relief structure 114, any part described herein of the integrated stress relief structure 114, and/or any part described herein of an integrated assembly that includes the integrated stress relief structure. For example, the method 500 may include forming one or more of the portion 308, the portion 312, the portion 316, the portion 320, the portion 326, the portion 328, the portion 336, the memory module 102, or the SSD module 202.

FIG. 6 is a flowchart of an example method 600 of forming an integrated assembly or memory device having a substrate with an integrated stress relief structure. In some implementations, and as described in greater detail in connection with FIGS. 7A-7C, one or more process blocks of FIG. 6 may be performed by various semiconductor manufacturing equipment.

As shown in FIG. 6, the method 600 may include receiving a substrate (e.g., the substrate 108) including an integrated stress relief structure (e.g., the stress relief structure 114) (block 610). As further shown in FIG. 6, the method 600 may include placing, on the substrate, a semiconductor component (e.g., the semiconductor die package 110). In some implementations, placing the semiconductor component on the substrate positions the semiconductor component proximate the integrated stress relief structure and electrically couples integrated circuitry of the semiconductor component with at least one electrically conductive trace of the substrate (block 620).

The method 600 may include additional aspects, such as any single aspect or any combination of aspects described below and/or in connection with one or more other methods described elsewhere herein.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the integrated stress relief structure 114, an integrated assembly that includes the integrated stress relief structure 114, any part described herein of the integrated stress relief structure 114, and/or any part described herein of an integrated assembly that includes the integrated stress relief structure. For example, the method 600 may include forming one or more of the portion 308, the portion 312, the portion 316, the portion 320, the portion 326, the portion 328, the portion 336, the memory module 102, or the SSD module 202.

FIGS. 7A-7C are diagrammatic views showing formation of a substrate (e.g., the substrate 108) including an integrated stress relief structure (e.g., the stress relief structure 114) at example process stages of an example process 700 of forming the substrate. In some implementations, the example process described below in connection with FIGS. 7A-7C may correspond to the method 500, one or more blocks of the method 500, the method 600, and/or one or more blocks of the method 600. However, the process described below is an example, and other example processes may be used to form one or more of the substrate 108, the integrated stress relief structure 114, the memory module 102, and/or the SSD module 202.

As shown in FIG. 7A, the process 700 may include receiving the substrate 108 (e.g., a multi-layer substrate, a PCB, a ceramic substrate). In some implementations, and as shown in FIG. 7A, the integrated circuit component 116 (e.g., an integrated circuit component including passive integrated circuitry) is joined with the substrate 108.

As shown in FIG. 7B, the process 700 may include forming the recessed region 402-1, the recessed region 402-2, the recessed region 402-3, and/or the recessed region 402-4 in the substrate 108. In some implementations, forming one or more of the recessed regions 402-1 through 402-4 exposes an edge of the dielectric layer 304 (e.g., an insulative layer) and/or an edge of the conductive layer 306. In some implementations, forming one or more of the recessed regions 402-1 through 402-4 includes an etch tool performing an etching operation, a routing tool performing a routing operation, or a laser tool performing a laser ablation operation, among other examples.

As further 7B, and in some implementations, the process 700 may include forming the plated via region 322 in the recessed region 402-2 or in the recessed region 402-4. In some implementations, forming the plated via region 322 includes a plating tool performing a plating operation, among other examples.

As shown in FIG. 7C, the process 700 may include forming the stress relief structure 114 (e.g., an integrated stress relief structure) having the portion 316 that extends into the substrate 108 (e.g., extends into the recessed region 402-2 or into the recessed region 402-4) and the portion 328 that extends partially into the substrate 108 (e.g., extends into the recessed region 402-1 or into the recessed region 402-3). In some implementations, forming the stress relief structure 114 forms an interfaces over the edge of the conductive layer 306 and/or the edge of the dielectric layer 304. In some implementations, forming the stress relief structure 114 includes a mold tool performing a compression molding operation, a transfer molding operation, or a dam-and-fill molding operation, among other examples.

In some implementations, as shown in FIG. 7C, forming the stress relief structure 114 includes using a composite material that includes an epoxy mold compound mixed with the thermally-conductive particulates 330. In such cases, a thermal conductivity of the thermally-conductive particulates 330 may be greater than a thermal conductivity of the epoxy mold compound. Further, and in some implementations and as shown in FIG. 7C, forming the stress relief structure 114 encapsulates the integrated circuit component 116.

As indicated above, the process steps described in connection with FIGS. 7A-7C are provided as examples. Other examples may differ from what is described with respect to FIGS. 7A-7C. Furthermore, the structure shown in FIG. 7C may be equivalent to the substrate 108 including the integrated stress relief structure 114 described elsewhere herein.

In some implementations, an integrated assembly includes a substrate, comprising: a conductive layer; and an integrated stress relief structure, comprising: a portion that passes through the conductive layer.

In some implementations, a semiconductor device assembly includes a multi-layer printed circuit board, comprising: a first side; and a second, opposite side; and an integrated stress relief structure, comprising: a first portion over the first side; and a second portion over the second, opposite side.

In some implementations, a semiconductor device assembly includes a multi-layer substrate, comprising: a recessed region that penetrates at least partially into the multi-layer substrate and exposes an edge of a conductive layer of the multi-layer substrate and an edge of a dielectric layer of the multi-layer substrate; and a stress relief structure, comprising: a portion in the recessed region that is over the edge of the conductive layer and the edge of the dielectric layer.

In some implementations, a method includes receiving a multi-layer substrate that includes a conductive layer and an insulative layer; forming a recessed region in the multi-layer substrate that exposes an edge of the conductive layer and an edge of the insulative layer; and forming an integrated stress relief structure including portions that extend into the recessed region to form an interface over the edge of the conductive layer and the edge of the insulative layer.

In some implementations, a method includes receiving a substrate including an integrated stress relief structure; and placing, on the substrate, a semiconductor component, wherein placing the semiconductor component on the substrate positions the semiconductor component proximate the integrated stress relief structure and electrically couples integrated circuitry of the semiconductor component with at least one electrically conductive trace of the substrate.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a substrate, comprising:
a conductive layer; and
an integrated stress relief structure, comprising:
a portion that passes through the conductive layer.

2. The integrated assembly of claim 1, wherein the portion is a first, vertical portion that joins with an edge of the conductive layer, and further comprising:
a second, horizontal portion that joins with a top surface of the substrate.

3. The integrated assembly of claim 1, wherein the integrated stress relief structure encapsulates and protects at least one passive integrated circuit component that is joined with the substrate.

4. The integrated assembly of claim 1, wherein conductive layer is an uppermost layer of the substrate.

5. The integrated assembly of claim 1, wherein the conductive layer is an intermediate layer of the substrate.

6. The integrated assembly of claim 1, wherein the integrated stress relief structure has an approximately planar surface region, and further comprising:
a label having at least a portion joined with the approximately planar surface region.

7. A semiconductor device assembly, comprising:
a multi-layer printed circuit board, comprising:
a first side; and
a second, opposite side; and
an integrated stress relief structure, comprising:
a first portion over the first side; and
a second portion over the second, opposite side.

8. The semiconductor device assembly of claim 7, wherein the integrated stress relief structure further comprises:
a third portion that passes through the multi-layer printed circuit board and that joins with the first portion and the second portion.

9. The semiconductor device assembly of claim 8, wherein the third portion fills a plated via region that passes through one or more conductive layers interspersed with one or more insulative layers.

10. The semiconductor device assembly of claim 8, wherein the third portion fills an un-plated via region that passes through one or more conductive layers interspersed with one or more insulative layers.

11. The semiconductor device assembly of claim 7, wherein at least one of the first portion or the second portion comprises:
a beam-like structure configured to absorb at least one of:
a bending stress,
a compressive stress, or
a tensile stress.

12. The semiconductor device assembly of claim 11, wherein the multi-layer printed circuit board further comprises:
an edge connector, and
wherein the beam-like structure is disposed proximate to the edge connector and along a path that is approximately parallel to the edge connector.

13. A semiconductor device assembly, comprising:
a multi-layer substrate, comprising:
a recessed region that penetrates at least partially into the multi-layer substrate and exposes an edge of a conductive layer of the multi-layer substrate and an edge of a dielectric layer of the multi-layer substrate; and
a stress relief structure, comprising:
a portion in the recessed region that is over the edge of the conductive layer and the edge of the dielectric layer.

14. The semiconductor device assembly of claim 13, wherein the multi-layer substrate has a first thermal conductivity, and
wherein the stress relief structure includes a second thermal conductivity that is greater that the first thermal conductivity.

15. The semiconductor device assembly of claim 13, wherein the stress relief structure comprises:
an epoxy mold compound that has a first thermal conductivity; and
thermally-conductive particulates that are dispersed within the epoxy mold compound and that have a second thermal conductivity,
wherein the second thermal conductivity is greater than the first thermal conductivity.

16. The semiconductor device assembly of claim 13, wherein the recessed region is an elongated channel that penetrates partially into the multi-layer substrate.

17. The semiconductor device assembly of claim 13, wherein the recessed region is a via that penetrates partially into the multi-layer substrate.

18. The semiconductor device assembly of claim 13, wherein the recessed region is an elongated channel that passes through the multi-layer substrate.

19. The semiconductor device assembly of claim 13, wherein the recessed region is a via that passes through the multi-layer substrate.

20. A method, comprising:
receiving a multi-layer substrate that includes a conductive layer and an insulative layer;
forming a recessed region in the multi-layer substrate that exposes an edge of the conductive layer and an edge of the insulative layer; and
forming an integrated stress relief structure including portions that extend into the recessed region to form an interface over the edge of the conductive layer and the edge of the insulative layer.

21. The method of claim 20, wherein forming the integrated stress relief structure includes:
encapsulating at least one passive integrated circuit component that is joined with the multi-layer substrate.

22. The method of claim 20, wherein forming the recessed region includes:
forming the recessed region using an etching operation,
forming the recessed region using a routing operation, or
forming the recessed region using a laser ablation operation.

23. The method of claim 20, further comprising:
plating least a portion of the recessed region prior to forming the integrated stress relief structure over the edge of the conductive layer and the edge of the insulative layer.

24. The method of claim 20, wherein forming the integrated stress relief structure includes:
forming the integrated stress relief structure using a composite material that includes an epoxy mold compound mixed with thermally-conductive particulates,
wherein a thermal conductivity of the thermally-conductive particulates is greater than a thermal conductivity of the epoxy mold compound.

25. The method of claim 20, further comprising:
placing a label on at least a portion of the integrated stress relief structure.
